(19) United States
(12) Patent Application Publication
(10) Pub. No.: US 2014/0295148 A1
(43) Pub. Date: Oct. 2, 2014

(54) PHOTOSENSITIVE RESIN COMPOSITION

(71) Applicant: Tamura Corporation, Tokyo (JP)

(72) Inventors: Koji Maekawa, Iruma-shi (JP); Naoya Kakiuchi, Iruma-shi (JP); Yoshiki Takebayashi, Iruma-shi (JP); Kazuhiro Horisawa, Iruma-shi (JP)

(73) Assignee: Tamura Corporation, Tokyo (JP)

(21) Appl. No.: 14/225,094

(22) Filed: Mar. 25, 2014

(30) Foreign Application Priority Data
Mar. 26, 2013 (JP) 2013-063393

(51) Int. Cl. G03F 7/038; H05K 1/03

(52) U.S. Cl. CPC G03F 7/038; H05K 1/0373
USPC 428/195.1; 430/280.1

(57) ABSTRACT

A photosensitive resin composition includes a carboxyl group-containing photosensitive resin, a photopolymerization initiator, a compound having an ethylenic unsaturated group, a non-reactive diluent, and an epoxy compound. The photopolymerization initiator includes an oxime ester compound and an aminocarbonyl compound having a tertiary amino group.

### CROSS REFERENCE TO RELATED APPLICATIONS

This application claims the benefit of Japanese Patent Application No. 2013-063393, filed Mar. 26, 2013, which is hereby incorporated by reference in its entirety.

### BACKGROUND

1. Technical Field

The present disclosure relates to a photosensitive resin composition suitable for a coating material such as a coating material for coating a conductor circuit pattern formed on a substrate such as a printed circuit board, and to a wiring board such as a printed circuit board coated with a cured material obtained by curing such a photosensitive resin composition.

2. Background

For example, in the related art, when forming a solder resist film on a printed circuit board, an exposure step is performed with a one-shot exposure method in which a photomask is provided on a coating of the printed circuit board and an entire surface of the printed circuit board is exposed to light. Recently, an exposure by a direct-write apparatus that directly writes an image using CAD data when exposing a photosensitive resin composition coated on a printed circuit board is drawing attention.

In a photosensitive resin composition used for the one-shot exposure method of the related art, an α-aminoalkyl phenone photopolymerization initiator (Japanese Laid-Open Patent Publication No. 2010-276859), an acyl phosphine oxide photopolymerization initiator (Japanese Laid-Open Patent Publication No. 2011-232402), a thioxanthone photopolymerization initiator (Japanese Laid-Open Patent Publication No. 2012-128442) or the like is used as a photopolymerization initiator.

However, in the direct-write exposure, photopolymerization reaction of the coating is difficult to progress due to disturbance by oxygen molecules during the exposure. Therefore, since sufficient light curing cannot be achieved at a deep part of the coating and undercut of a cured coating is produced, there is a drawback that a shape as a solder dam for blocking a flow of solder is degraded. Further, since the shape as a solder dam is degraded, it cannot be adapted to a fine-pitched circuit pattern, and there is a drawback that a line may peel or become defective, in other words, the resolution may decrease.

### SUMMARY

In view of the foregoing, it is an object of the present disclosure to provide a photosensitive resin composition suitable for forming an insulating coating such as a solder resist film that can prevent undercutting of the cured coating even in a case of exposure by a direct-write apparatus that directly writes an image.

In order to achieve the aforementioned object, an aspect of the invention is a photosensitive resin composition including (A) a carboxyl group-containing photosensitive resin, (B) a photopolymerization initiator, (C) a compound having an ethylenic unsaturated group, (D) a non-reactive diluent, and (E) an epoxy compound, (B) the photopolymerization initiator including (B-1) an oxime ester compound and (B-2) an aminocarbonyl compound having a tertiary amino group.

Another aspect of the present disclosure is a photosensitive resin composition wherein 6.0 parts by mass to 12.0 parts by mass of (B-2) the aminocarbonyl compound having a tertiary amino group is contained with respect to 100 parts by mass of (A) the carboxyl group-containing photosensitive resin.

Another aspect of the present disclosure is a photosensitive resin composition wherein 0.2 parts by mass to 0.4 parts by mass of (B-1) the oxime ester compound is contained with respect to 100 parts by mass of (A) the carboxyl group-containing photosensitive resin.

Still another aspect of the present disclosure is a photosensitive resin composition further including (F) a coloring agent.

Yet another aspect of the present disclosure is a printed circuit board having a cured film obtained by photo-curing the aforementioned photosensitive resin composition.

### Effect of the Invention

According to an aspect of the present disclosure, by using an oxime ester compound and an aminocarbonyl compound having a tertiary amino group together as a polymerization initiator, even in a case of exposure by the direct-write apparatus that directly writes an image, sufficient light curing can be achieved up to a deep part of the coating and undercutting of the cured coating can be suppressed without degrading transmittance and sensitivity of the cured coating. Also, since undercutting of the cured coating can be suppressed even in a case of exposure by a direct-write apparatus that directly writes an image, peeling or defects in the line can be prevented and lowering of the resolution can be prevented. Further, as has been described above, since exposure can be performed by a direct-write apparatus, a photomask is not required in the exposure step and a patterning step of the cured coating can be simplified.

According to an aspect of the present disclosure, since 6.0 parts by mass to 12.0 parts by mass of the aminocarbonyl compound having a tertiary amino group is contained with respect to 100 parts by mass of the carboxyl group-containing photosensitive resin, undercutting of the cured coating can be positively suppressed.

According to an aspect of the present disclosure, since 0.2 parts by mass to 0.4 parts by mass of the oxime ester compound is contained with respect to 100 parts by mass of the carboxyl group-containing photosensitive resin, undercutting of the cured coating can be positively suppressed while improving the sensitivity of the coating.

### DETAILED DESCRIPTION

A photosensitive resin composition of the present disclosure will be described in detail. The photosensitive resin composition of the present disclosure includes (A) a carboxyl group-containing photosensitive resin, (B) a photopolymerization initiator, (C) a compound having an ethylenic unsaturated group, (D) a non-reactive diluent, and (E) an epoxy compound, (B) the photopolymerization initiator includes (B-1) an oxime ester compound and (B-2) an aminocarbonyl compound having a tertiary amino group.

(A) Carboxyl Group-Containing Photosensitive Resin

A carboxyl group-containing photosensitive resin may be a photosensitive carboxyl group-containing resin having one or more photosensitive unsaturated double bond, but it is not particularly limited thereto. An example of the carboxyl group-containing photosensitive resin is a polybasic acid modified radical polymerizable unsaturated monocarboxylated epoxy resin such as polybasic acid modified epoxy (meta)acrylate that is obtained by reacting at least a part of the epoxy groups of a multifunctional epoxy resin having two or more epoxy groups in a single molecule with a radical polymerizable unsaturated monocarboxylic acid such as an acrylic acid and a methacrylate (hereinafter, may also be referred to as “(meta)acrylic acid”) to obtain a radical polymerizable unsaturated monocarboxylated epoxy resin such as epoxy (meta)acrylate, and further reacting a produced hydroxyl group with polybasic acid or an anhydride thereof.

Any of the aforementioned multifunctional epoxy resins can be used as long as it is an epoxy resin with two or more functions. An epoxy equivalent weight of the multifunctional epoxy resin is preferably less than or equal to 1000, and more preferably 100 to 500, but it is not particularly limited thereto. The multifunctional epoxy resin may be, for example, a rubber modified epoxy resin such as a biphenyl epoxy resin, a naphthalene epoxy resin, a dicyclopentadiene epoxy resin and a silicone modified epoxy resin, an c-caprolactone modified epoxy resin, a phenol novolac epoxy resin such as bisphenol A, bisphenol F and bisphenol AD, a cresol novolac epoxy resin such as an o-cresol novolac type, a bisphenol A novolac epoxy resin, a cyclic aliphatic multifunctional epoxy resin, a glycidyl ester multifunctional epoxy resin, a glycidyl amine type multifunctional epoxy resin, a heterocyclic multifunctional epoxy resin, a bisphenol modified novolac epoxy resin, a multifunctional modified novolac epoxy resin, a condensated epoxy resin of phenols and aromatic aldehyde having a phenolic hydroxyl group, or the like. Also, it is possible to use those obtained by introducing a halogen atom such as Br and Cl into these resins. These epoxy resin may be used alone or as a mixture of two or more kinds.

The radical polymerizable unsaturated monocarboxylic acid may be, for example, an acrylic acid, a methacrylic acid, a crotonic acid, and a cinnamic acid, among which an acrylic acid and a methacrylic acid are preferable, but it is not particularly limited thereto. A reaction method of the epoxy resin and the radical polymerizable unsaturated monocarboxylic acid is not particularly limited, and, for example, the epoxy resin and the radical polymerizable unsaturated monocarboxylic acid can be reacted by being heated in a suitable diluent.

A polybasic acid or a polybasic acid anhydride reacts with a hydroxyl group that is generated by a reaction between an epoxy resin and a radical polymerizable unsaturated monocarboxylic acid to introduce a free carboxyl group of the isolation into the resin. The polybasic acid or the anhydrides thereof are not limited, and may either be saturated or unsaturated. The polybasic acid may be, for example, succinic acid, maleic acid, adipic acid, citric acid, phthalic acid, tetrahydrophthalic acid, 3-methyl tetrahydrophthalic acid, 4-methyl tetrahydrophthalic acid, 3-ethyl tetrahydrophthalic acid, 4-ethyl tetrahydrophthalic acid, hexahydrophthalic acid, 3-methyl hexahydrophthalic acid, 4-methyl hexahydrophthalic acid, 3-ethyl hexahydrophthalic acid, 4-ethyl hexahydrophthalic acid, methyl tetrahydrophthalic acid, methyl hexahydrophthalic acid, endo-methylene tetrahydrophthalic acid, methyl endo-methylene tetrahydrophthalic acid, trimerit acid, pyromellitic acid and diglycolic acid, and anhydrides thereof may be the polybasic acid anhydrides. These compounds may be used alone or may be used as a mixture of two or more kinds.

The aforementioned polybasic acid modified unsaturated monocarboxylated epoxy resin can also be used as a carboxyl group-containing photosensitive resin, but may also be a carboxyl group-containing photosensitive resin having an improved photosensitivity obtained by further introducing a radical polymerizable unsaturated group by reacting the aforementioned polybasic acid modified unsaturated monocarboxylated epoxy resin with a glycidyl compound having one or more radical polymerizable unsaturated group and an epoxy group, as necessary.

Such a carboxyl group-containing photosensitive resin having an improved photosensitivity is a resin which has a high photopolymerization reactivity and an improved photosensitive characteristic, since a radical polymerizable unsaturated radical is bonded to a side chain of a polybasic acid modified unsaturated monocarboxylated epoxy resin skeleton by the reaction of the aforementioned glycidyl compound. A compound having one or more radical polymerizable unsaturated radical and an epoxy group includes, for example, glycidyl acrylate, glycidyl methacrylate, allyl glycidyl ether, and pentaerythritol triacrylate monoglycidyl ether. Note that, a single molecule may have a plurality of glycidyl groups. The aforementioned compound having one or more radical polymerizable unsaturated radical and epoxy groups may be used alone or as a mixture of two or more kinds.

An acid value of the carboxyl group-containing photosensitive resin is not particularly limited. However, concerning a reliable alkali developing, a lower limit thereof is preferably 30 mgKOH/g and particularly preferably 40 mgKOH/g. An upper limit of the acid value is preferably 200 mgKOH/g, concerning dissolution prevention of an exposure section by an alkaline developer, and particularly preferably 150 mgKOH/g, concerning moisture resistance and prevention of degradation of electric characteristics.

Also, a weight-average molecular weight of the carboxyl group-containing photosensitive resin is not particularly limited. However, its lower limit is preferably 3000 concerning toughness and a tack free property of a cured material, and particularly preferably 5000. On the other hand, an upper limit of the weight average molecular weight is preferably 200000 concerning smooth alkali developability, and particularly preferably 50000.

For example, a carboxyl group-containing photosensitive resin that is commercially available may include, for example, ZAR-2000, ZFR-1122 and FLX-2089 (all manufactured by Nippon Kayaku Co., Ltd.), Cyclomer P (ACA) Z-250 (manufactured by Daicel Chemical Industries, Ltd.) and Ripoxy SP-4621 (manufactured by Showa Highpolymer Co., Ltd.). These resins may be used alone and as a mixture of two or more kinds.

(B) Photopolymerization Initiator

With a photosensitive resin composition of the present disclosure, (B-1) an oxime ester compound and (B-2) an aminocarbonyl compound having tertiary amino group are used together as a photopolymerization initiator. Since a photopolymerization initiator to be used includes an oxime ester compound and an aminocarbonyl compound having a tertiary amino group, the coating is photo-cured sufficiently to its deep part even in a case of exposure by a direct-write apparatus that directly writes an image. Accordingly, during the development after the exposure step, undercutting of the cured coating can be suppressed.

(B-1) Oxime Ester Compound

An oxime ester compound is a compound having an oxime ester group such as, for example, 1,2-octanedione, 1-[4-(phenylthio)-2-(O-benzoyloxime)], ethanone 1-[9 ethyl-6-(2-methyl benzoyl)-9H-carbazole-3-yl]-1-(0-acetyl oxime) and 2-(acetyloxyimino methyl)thioxanthene-9-one. Of these, concerning pyrolytic property, ethanone 1-[9 ethyl-6-(2-methyl benzoyl)-9H-carbazole-3-yl]-1-(0-acetyl oxime) is preferable. These may be used alone or as a mixture of two or more kinds.

Content of the oxime ester compound is not particularly limited. For example, for positively suppressing undercutting of the cured coating even in a case of an exposure by the direct-write apparatus, a lower limit thereof is preferably 0.1 parts by mass with respect to 100 parts by mass of the carboxyl group-containing photosensitive resin, and particularly preferably 0.2 parts by mass for improving the sensitivity during the development. An upper limit is, for example, for preventing a decrease in the sensitivity, preferably 0.6 parts by mass with respect to 100 parts by mass of the carboxyl group-containing photosensitive resin, and particularly preferably 0.4 parts by mass for positively suppressing undercutting in the cured coating even in a case of an exposure by the direct-write apparatus and obtaining an improved cross-sectional shape.

(B-2) Aminocarbonyl Compound having a Tertiary Amino Group

An aminocarbonyl compound having a tertiary amino group is a compound having an amino carbonyl group having a tertiary amino group, and acts as an amine hydrogen donor (i.e., a hydrogen donor having one or more tertiary amino group group). “Hydrogen donor” is a compound that provides hydrogen to a radical produced from an oxime ester compound used together as a photopolymerization initiator during exposure. An exposure property improves by using an aminocarbonyl compound having a tertiary amino group acting as a hydrogen donor together in addition to an oxime ester compound. The aminocarbonyl compound having a tertiary amino group include, for example, ethyl-4-(dimethylamino)benzoate, 2-n-butoxyethyl-4-(dimethylamino)benzoate, methyl-4-(dimethylamino)benzoate, isoamyl-4-(dimethylamino)benzoate, 2-(dimethylamino)ethyl benzoate, 4,4′-bis-4-dimethyl aminobenzophenone, 4,4′-bis-4-diethyl aminobenzophenone, 2-ethylhexyl-4-(dimethylamino)benzoate. Of these, for obtaining a cured coating with an improved cross-sectional shape, ethyl-4-(dimethylamino)benzoate, 2-n-butoxy ethyl-4-(dimethylamino)benzoate, and 2-ethylhexyl-4-(dimethylamino)benzoate are desirable. These may be used alone or as a mixture of two or more kinds.

Content of the aminocarbonyl compound having tertiary amino group is not particularly limited. For example, for positively suppressing undercutting of the cured coating even in a case of an exposure by the direct-write apparatus, a lower limit thereof is preferably 0.3 parts by mass with respect to 100 parts by mass of the carboxyl group-containing photosensitive resin, and particularly preferably 0.6 parts by mass for improving the sensitivity during the development. An upper limit is, for example, for preventing a decrease in the sensitivity, preferably 15.0 parts by mass with respect to 100 parts by mass of the carboxyl group-containing photosensitive resin, and particularly preferably 12.0 parts by mass for positively suppressing an occurrence of an undercut in the cured coating and obtaining an improved cross-sectional shape of the cured coating.

A mixing ratio between the oxime ester compound and the aminocarbonyl compound having a tertiary amino group is not particularly limited. For example, the mixing ratio is, for obtaining a good sensitivity during the development, preferably 20 parts by mass to 60 parts by mass of the aminocarbonyl compound having a tertiary amino group with respect to 1.0 parts by mass of the oxime ester compound, and for obtaining a cured coating having an improved cross-sectional shape in addition to a good sensitivity, particularly preferably 30 parts by mass to 50 parts by mass of the aminocarbonyl compound having a tertiary amino group.

Further, a total amount of contents of the oxime ester compound and the aminocarbonyl compound having a tertiary amino group is not particularly limited. However, a lower limit thereof is, for further improving the sensitivity during the developing, preferably 6.0 parts by mass with respect to 100 parts by mass of the carboxyl group-containing photosensitive resin and particularly preferably 9.0 parts by mass, for positively suppressing undercutting of the cured coating even in a case of an exposure by the direct-write apparatus. On the other hand, its upper limit is, for example, for preventing a decrease in the sensitivity during the development, preferably 15.0 parts by mass with respect to 100 parts by mass of the carboxyl group-containing photosensitive resin, and, for obtaining the cured coating having an improved cross-sectional shape, particularly preferably 13.0 parts by mass.

With the photosensitive resin composition of the present disclosure, in addition to the photopolymerization initiator which are a photopolymerization initiator which is the aforementioned oxime ester compound and a photopolymerization initiator which is an aminocarbonyl compound having a tertiary amino group, photopolymerization intiators other than these (hereinafter, referred to as “other photopolymerization initiators”) may be used together to improve curability of a surface of a curable material.

Other photopolymerization initiators are not particularly limited, and an α-aminoalkyl phenone photopolymerization initiator, an acyl phosphine oxide photopolymerization initiator, and the thioxanthone photopolymerization initiator may also be used. Other photopolymerization initiators may be, for example, benzoin, benzoin methyl ether, benzoin ethyl ether, benzoin isopropyl ether, benzoin-n-butyl ether, benzoin isobutyl ether, acetophenone, 2,2-dimethoxy-2-phenyl acetophenone, 2,2-diethoxy-2-phenyl acetophenone, 2-hydroxy-2-methyl-l-phenyl propane-l-one, 1-hydroxy cyclohexyl phenyl ketone, 2-methyl-1-[4-(methylthio)phenyl]-2-morpholino-propane-1-one, 2-benzyl-2-dimethylamino-1-morpholino phenone-butanone-1, 2-(dimethylamino)-2-[(4-methylphenyl)methyl]-1-[4-(4-morpholinyl)phenyl]-1-butanone, 4-(2-hydroxy ethoxy)phenyl-2-(hydroxy-2-propyl)ketone, benzophenone, p-phenyl benzophenone, dichlorobenzophenone, 2-methyl anthraquinone, 2-ethyl anthraquinone, 2-tertiary butyl anthraquinone, 2-amino anthraquinone, 2-methyl thioxanthone, 2-ethyl thioxanthone, 2-chloro thioxanthone, 2,4-dimethyl thioxanthone, 2,4-diethyl thioxanthone, benzyl dimethyl ketal, acetophenone dimethyl ketal, 2,4,6-trimethyl benzoyl-diphenyl-phosphine oxide, bis(2,4,6-trimethyl benzoyl)-phenyl phosphine oxide, bis(2,6-dimethyl benzoyl)-2,4,4-trimethyl-pentyl phosphine oxide, (2,4,6-trimethyl benzoyl)ethoxyphenyl phosphine oxide are included. These may be used alone or as a mixture of two or more kinds.

The contents of other photopolymerization initiators are not particularly limited, but it is preferably less than or equal to 10 parts by mass and particularly preferably 2.0 parts by mass to 8.0 parts by mass with respect to 100 parts by mass of the carboxyl group-containing photosensitive resin.

(C) Compound having an Ethylene Unsaturated Group

A compound having an ethylene unsaturated group is, for example, a photopolymerizable monomer that is a compound having at least one polymeric double bond per molecule. The compound having an ethylene unsaturated group is used for obtaining a curable material having an acid resistance, a heat resistance, and an alkali resistance by being photocured by irradiation of an active energy ray such as ultraviolet radiation so as to achieve sufficient photocuring of the photosensitive resin composition. The compound having an ethylene unsaturated group is not particularly limited as long as it is the aforementioned compound, and may be, for example, methacrylate 2-hydroxyethyl, phenoxyethyl methacrylate, diethylene glycol monomethacrylate, 2-hydroxy-3-phenoxypropyl acrylate, 1,4-butanediol di(meta)acrylate, 1,6-hexanediol di(meta)acrylate, neopentylglycol di(meta)acrylate, diethylene glycol di(meta)acrylate, neopentylglycol adipate di(meta)acrylate, hydroxy pivalic acid neopentylglycol di(meta)acrylate, dicyclopentanyl di(meta)acrylate, caprolactone modified dicyclopentenyl di(meta)acrylate, ethylene oxide modified phosphoric acid di(meta)acrylate, allyl cyclohexyl di(meta)acrylate, isocyanurate di(meta)acrylate, trimethylol propane tri(meta)acrylate, ditrimethylol propane tetra(meta)acrylate, dipentaerythritol tri(meta)acrylate, dipentaerythritol tri(meta)acrylate, pentaerythritol tri(meta)acrylate, propylene oxide modified trimethylol propane tri(meta)acrylate, tris(acryloxy ethyl)isocyanurate, propionate modified dipentaerythritol penta(meta)acrylate, dipentaerythritol hexa(meta)acrylate, caprolactone modified dipentaerythritol hexa(meta)acrylate, and multifunctional urethane acrylate. These may be used alone or as a mixture of two or more kinds.

The content of the compound having an ethylene unsaturated group is not particularly limited and it is, for example, preferably 2.0 to 500 parts by mass and particularly preferably 10 to 300 parts by mass with respect to 100 parts by mass of the carboxyl group-containing photosensitive resin.

(D) Non-reactive Diluent

The non-reactive diluent is for regulating viscosity and a drying property of the photosensitive resin composition. For example, the non-reactive diluent includes an organic solvent. The organic solvent may be, for example, ketones such as methyl ethyl ketone and cyclohexanone, aromatic hydrocarbons such as toluene and xylene, alcohols such as methanol, isopropanol and cyclohexanol, alicyclic hydrocarbons such as cyclohexane and methyl cyclohexane, petroleum solvents such as petroleum ether and petroleum naphtha, cellosolves such as cellosolve and butyl cellosolve, carbitols such as carbitol and butyl carbitol, esters such as ethylacetate, butyl acetate, cellosolve acetate, butyl cellosolve acetate, carbitol acetate, butyl carbitol acetate, ethyl diglycol acetate, and diethylene glycol monomethyl ether acetate. These may be used alone or as a mixture of two or more kinds.

The content of the non-reactive diluent is not particularly limited and may be selected as appropriate. For example, it is preferably 10 parts by mass to 100 parts by mass with respect to 100 parts by mass of the carboxyl group-containing photosensitive resin.

(E) Epoxy Compound

The epoxy compound is for obtaining a cured material such as a cured coating having a sufficient mechanical strength by increasing a crosslink density of the cured material. An epoxy compound is, for example, an epoxy resin. The epoxy resin may be, for example, a bisphenol A epoxy resin, a bisphenol F type epoxy resin, a novolac epoxy resin (biphenyl novolac epoxy resin, a phenol novolac epoxy resin, an o-cresol novolac epoxy resin, a p-tert-butyl phenol novolac type, etc.,), a bisphenol F or bisphenol S epoxy resin that obtained by reacting bisphenol F or bisphenol S with an epichlorohydrin, an alicyclic epoxy resin further having a cyclohexene oxide group, a tricyclodecane oxide group, a cyclopentene oxide group, triglycidyl isocyanurate having triazine rings such as a tris(2,3-epoxypropyl)isocyanurate and a triglycidyl tris(2-hydroxyethyl)isocyanurate, dicyclopentadiene epoxy resin, adamantane epoxy resin. These may be used alone or as a mixture of two or more kinds.

The content of the epoxy compound is not particularly limited, but for obtaining a cured coating with a sufficient mechanical strength without losing flexibility, it is preferably 10 parts by mass to 100 parts by mass and particularly preferably 20 to 70 parts by mass with respect to 100 parts by mass of the carboxyl group-containing photosensitive resin.

The photosensitive resin composition of the present disclosure may contain, in addition to the aforementioned components (A) to (E), various additive components such as (F) a coloring agent, an extender pigment, an antifoaming agent, and various additive agents, as necessary.

(F) Coloring Agent

The coloring agent is not particularly limited and may be pigments, coloring matters or the like, and any of a white coloring agent, a blue coloring agent, a yellow coloring agent, a black coloring agent or the like may be used. The aforementioned coloring agent may be, for example, an inorganic coloring agent such as titanium oxide which is a white coloring agent and carbon black which is a black coloring agent, and an organic coloring agent such as phthalocyanines such as phthalocyanine green and phthalocyanine blue, and anthraquinones.

The extender pigment is for improving strength and stiffness of the cured material and may be, for example, barium sulfate, silica, alumina, talc, mica, and the like. The antifoaming agent is not particularly limited, but may be of a silicone type, a hydrocarbon type and an acrylic type. Also, various additives include a latent curing agent such as dicyandiamide (DICY) and derivatives thereof, melamine and derivatives thereof, an antioxidant, and a coupling agent.

A method of manufacturing a photosensitive resin composition of the aforementioned present disclosure is not limited to a particular method, but, may be manufactured by, for example, after blending each of the aforementioned components at a predetermined ratio, kneading or mixing at a room temperature with a kneading means such as a three roll mill, a ball mill and a sand mill or a stirring means such as a super mixer and a planetary mixer. Also, before the aforementioned kneading or mixing, a preliminary kneading or a preliminary mixing may be performed.

Next, an operation of the photosensitive resin composition of the aforementioned present disclosure will be described. Herein, a case in which a photosensitive resin composition of the present disclosure is applied on a circuit board as a solder resist film will be described as an example.

A photosensitive resin composition of the present disclosure obtained as described above is, for example, using a known applying technique such as screen printing, a spray coater, a bar coater, an applicator, a blade coater, a knife coater, a roll coater, and a photogravure coater, applied with a desired thickness to a printed circuit board, which has a circuit pattern formed by etching a copper foil. After applying, in order to volatilize the solvent (non-reactive diluent) in a photosensitive resin composition, a preliminary drying is performed in which heating is performed at a temperature of 60 to 80° C. for about 15 to 60 minutes to form a tack-free coating. Then, on the applied photosensitive resin composition, an active energy ray (e.g., ultraviolet radiation) is directly irradiated depending on a desired pattern with the direct-write apparatus, and the coating is photocured into such a pattern. Then, the coating is developed by removing an unexposed region with a dilute alkali aqueous solution. A spray method, a shower method or the like may be used for the aforementioned developing method, and a dilute alkali aqueous solution includes 0.5% to 5% of a sodium carbonate aqueous solution, but it is not particularly limited thereto. Then, by performing a post-cure with a hot blast circle-type heat oven or the like at 130-170° C. for 20 to 80 minutes, the developed coating is thermally cured and a cured coating having an intended pattern can be formed on a printed circuit board.

An electronic circuit unit is formed by soldering electronic components, by a jet soldering method, a reflow soldering method, or the like, on a circuit board coated with the solder resist film thus obtained.

### EXAMPLE

Hereinafter, examples of the present disclosure will be described, but the present disclosure is not limited to these examples as long as it does not depart from the spirit of the invention.

### Examples 1 to 10 and Comparative Examples 1 to 5

Components shown in Tables 1-1 and 1-2 were blended at a blending ratio shown in Tables 1-1 and 1-2 and mixed and dispersed at a room temperature using a three roll mill to prepare a photosensitive resin composition to be used in Examples 1 to 10 and Comparative Examples 1 to 5. The blending amount of each component shown in Tables 1-1 and 1-2 are indicated in parts by mass unless otherwise specified.

TABLE 1-1

| | | | EXAMPLE | EXAMPLE | EXAMPLE | EXAMPLE | EXAMPLE |
|---|---|---|---|---|---|---|---|
| | | | 1 | 2 | 3 | 4 | 5 |
| (A) CARBOXYL GROUP-CONTAINING | | ZFR-1122 | 100 | 100 | 100 | 100 | 100 |
| PHOTOSENSITIVE RESIN | | | | | | | |
| (B) PHOTOPOLY- | (B-1) OXIME ESTER | OXE-02 | 0.2 | 0.2 | 0.4 | 0.2 | 0.4 |
| MERIZATION | COMPOUND | | | | | | |
| INITIATOR | (B-2) AMINOCARBONYL | SPEEDCURE EDB | 12 | 9 | 9 | 12 | 12 |
| | COMPOUND HAVING | SPEEDCURE BEDB | | | | | |
| | TERTIARY AMINO | Chemcure EHA | | | | | |
| | GROUP | | | | | | |
| | (B-3) OTHER | IRGACURE 907 | 4 | 4 | 4 | 4 | 4 |
| | PHOTOPOLY- | IRGACURE 819 | | | | | |
| | MERIZATION | SPEEDCURE DETX | 0.6 | 0.6 | 0.6 | 0.6 | 0.6 |
| | INITIATORS | | | | | | |
| (C) COMPOUND HAVING ETHYLENE | | KRM8296 | 30 | 30 | 30 | 30 | 30 |
| UNSATURATED GROUP | | | | | | | |
| (D) NON-REACTIVE DILUENT | | DIETHYLENE GLYCOL | 10 | 10 | 10 | 10 | 10 |
| | | MONOMETHYL | | | | | |
| | | ETHER ACETATE | | | | | |
| (E) EPOXY COMPOUND | | YDF-2004 | 60 | 60 | 60 | 60 | 60 |
| (F) COLORING AGENT | | CARBON BLACK | 1.3 | 1.3 | 1.3 | 1.3 | 1.3 |
| | | C. I. Pigment Blue 15:3 | 0.4 | 0.4 | 0.4 | 0.4 | 0.4 |
| EXTENDER PIGMENT | | OK412 | 10 | 10 | 10 | 10 | 10 |
| | | | EXAMPLE | EXAMPLE | EXAMPLE | EXAMPLE | EXAMPLE |
| | | | 6 | 7 | 8 | 9 | 10 |
| (A) CARBOXYL GROUP-CONTAINING | | ZFR-1122 | 100 | 100 | 100 | 100 | 100 |
| PHOTOSENSITIVE RESIN | | | | | | | |
| (B) PHOTOPOLY- | (B-1) OXIME ESTER | OXE-02 | 0.3 | 0.3 | 0.3 | 0.2 | 0.4 |
| MERIZATION | COMPOUND | | | | | | |
| INITIATOR | (B-2) AMINOCARBONYL | SPEEDCURE EDB | 12 | | | 6 | 15 |
| | COMPOUND HAVING | SPEEDCURE BEDB | | 12 | | | |
| | TERTIARY AMINO | Chemcure EHA | | | 12 | | |
| | GROUP | | | | | | |
| | (B-3) OTHER | IRGACURE 907 | 4 | 4 | 4 | 4 | 4 |
| | PHOTOPOLY- | IRGACURE 819 | | | | | |
| | MERIZATION | | | | | | |
| | INITIATORS | SPEEDCURE DETX | 0.6 | 0.6 | 0.6 | 0.6 | 0.6 |

| | | | | | | |
|---|---|---|---|---|---|---|
| (C) COMPOUND HAVING ETHYLENE | KRM8296 | 30 | 30 | 30 | 30 | 30 |
| UNSATURATED GROUP | | | | | | |
| (D) NON-REACTIVE DILUENT | DIETHYLENE GLYCOL | 10 | 10 | 10 | 10 | 10 |
| | MONOMETHYL | | | | | |
| | ETHER ACETATE | | | | | |
| (E) EPOXY COMPOUND | YDF-2004 | 60 | 60 | 60 | 60 | 60 |
| (F) COLORING AGENT | CARBON BLACK | 1.3 | 1.3 | 1.3 | 1.3 | 1.3 |
| | C. I. Pigment Blue 15:3 | 0.4 | 0.4 | 0.4 | 0.4 | 0.4 |
| EXTENDER PIGMENT | OK412 | 10 | 10 | 10 | 10 | 10 |

TABLE 1-2

| | | | COMPAR- | COMPAR- | COMPAR- | COMPAR- | COMPAR- |
|---|---|---|---|---|---|---|---|
| | | | ATIVE | ATIVE | ATIVE | ATIVE | ATIVE |
| | | | EXAM- | EXAMP- | EXAMP- | EXAM- | EXAM- |
| | | | PLE 1 | LE 2 | LE 3 | PLE 4 | PLE 5 |
| (A) CARBOXYL GROUP-CONTAINING | | ZFR-1122 | 100 | 100 | 100 | 100 | 100 |
| PHOTOSENSITIVE RESIN | | | | | | | |
| (B) PHOTOPOLY- | (B-1) OXIME ESTER | OXE-02 | | 0.4 | | 0.3 | |
| MERIZATION | COMPOUND | | | | | | |
| INITIATOR | (B-2) AMINOCARBONYL | SPEEDCURE EDB | | | 15 | | |
| | COMPOUND HAVING | SPEEDCURE BEDB | | | | | |
| | TERTIARY AMINO | Chemcure EHA | | | | | |
| | GROUP | | | | | | |
| | (B-3) OTHER | IRGACURE 907 | 10 | 4 | 4 | | 20 |
| | PHOTOPOLY- | IRGACURE 819 | | | | 10 | |
| | MERIZATION | SPEEDCURE DETX | 1 | 0.6 | 0.6 | 0.6 | 2 |
| | INITIATORS | | | | | | |

| | | | | | | |
|---|---|---|---|---|---|---|
| (C) COMPOUND HAVING ETHYLENE | KRM8296 | 30 | 30 | 30 | 30 | 30 |
| UNSATURATED GROUP | | | | | | |
| (D) NON-REACTIVE DILUENT | DIETHYLENE GLYCOL | 10 | 10 | 10 | 10 | 10 |
| | MONOMETHYL | | | | | |
| | ETHER ACETATE | | | | | |
| (E) EPOXY COMPOUND | YDF-2004 | 60 | 60 | 60 | 60 | 60 |
| (F) COLORING AGENT | CARBON BLACK | 1.3 | 1.3 | 1.3 | 1.3 | 0.6 |
| | C. I. Pigment Blue 15:3 | 0.4 | 0.4 | 0.4 | 0.4 | 0.4 |
| EXTENDER PIGMENT | OK412 | 10 | 10 | 10 | 10 | 10 |

Note that the details of each component in Tables 1-1 and 1-2 are as follows.

(A) Carboxyl Group-Containing Photosensitive Resin
ZFR-1122: Acid anhydride additive of bisphenol F epoxyacrylate, manufactured by Nippon Kayaku Co., Ltd.

(B) Photopolymerization Initiator

(B-1) Oxime Ester Compound
OXE-02: Ethanone, 1-[9-ethyl-6-(2-methyl benzoyl)-9H-carbazole-3-yl]-,1-(0-acetyl oxime), manufactured by BASF AG.

(B-2) Aminocarbonyl Compound Having a Tertiary Amino Group
SPEEDCURE EDB: Ethyl-4-(dimethylamino)benzoate, manufactured by LAMBSON LTD.
SPEEDCURE BEDB: 2-n butoxyethyl-4-(dimethylamino)benzoate, manufactured by LAMBSON LTD.
Chemcure EHA: 2-ethylhexyl-4-(dimethylamino)benzoate, manufactured by Chembridge International Corp.

(B-3) Other Photopolymerization Initiators
Irgacure 907: 2-methyl-1-[4-(methylthio)phenyl]-2-morpholino-propane-1-on (α-aminoalkyl phenone photopolymerization initiators), manufactured by Ciba Specialty Chemicals Corporation.
Irgacure 819: bis(2,4,6-trimethyl benzoyl)-phenyl phosphine oxide (acyl phosphine oxide photopolymerization initiator), manufactured by Ciba Specialty Chemicals Corporation.
   SPEEDCURE DETX: 2,4-diethyl thioxanthone (thioxanthone photopolymerization initiator), manufactured by LAMBSON LTD.

(C) Compound having an Ethylene Unsaturated Group
KRM8296: 3-functional urethane acrylate, weight average molecular weight 2770, manufactured by Daicel-cytec Co., Ltd.

(E) Epoxy Compound
YDF-2004: glycidyl ether modified material (alias: Bisphenol F epoxy resin) of phenolic-formaldehyde polycondensates by epichlorohydrin, manufactured by Tohto Kasei Corporation.

(F) Coloring Agent
Carbon black: manufactured by Denki Kagaku Kogyo Corporation, acetylene black.
C. I. Pigment Blue 15: 3: phthalocyanine, manufactured by Toyo Ink Manufacturing Corporation.

About Other Components
OK412: Silicon dioxide, manufactured by Evonik Degussa AG Corporation.

Test Piece Manufacturing Step

A wiring board obtained by forming a circuit pattern on a resin-coated-copper foil (Cu thickness 12.5 μm) having a polyimide film (manufactured by Toray Du Pont Co., Ltd., “Kapton 100H”, thickness 25 μm) was subjected to surface treatment by dilute sulphuric acid (5 mass %), and thereafter, photosensitive resin compositions of Examples 1 to 10 and Comparative Examples 1 to 5 prepared as above were respectively applied thereto by screen printing. After application, a preliminary drying was performed at 80° C. for 20 minutes in a BOX furnace. After the preliminary drying, 250 mJ/cm² of an ultraviolet radiation of a wavelength of 250 to 450 nm was exposed on a coating in an exposure apparatus (direct-write exposure machine manufactured by Oak corporation, “DilMPACTMms60”) and was developed using a 1% sodium carbonate aqueous solution at a development temperature of 30° C. at a spray pressure of a development pressure of 0.2 MPa. After the development, a cured coating was formed on a wiring board by performing a post-cure at 150° C. for 60 minutes in a BOX furnace. The thickness of the cured coating was 20 to 23 μm.

Evaluation

(1) Transmittance

Except that a polyethylene terephthalate (PET) film (manufactured by Oak corporation, thickness 125 μm) was used as the substrate instead of the polyimide film, a photosensitive resin composition prepared as described above was applied in conformity with the aforementioned test piece manufacture step. A test piece thus-obtained was evaluated with the following criterion by measuring a total light transmittance in a wavelength range of 330 nm to 450 nm using a U-3310 spectrophotometer manufactured by Hitachi High-Technologies Corporation in conformity with JIS K-7105 and JIS K-7136.
◯: Total light transmittance is less than or equal to 10%.
Δ: Total light transmittance is greater than 10% and less than 15%.
×: Total light transmittance is greater than or equal to 15%.

(2) Sensitivity

A test piece was prepared by adhering a step tablet for sensitivity measurement (manufactured by Kodak Corporation, 14 steps) on a coating of the wiring board that has been processed similarly by the aforementioned test piece manufacture step up to a preliminary drying step, and irradiating an ultraviolet radiation (wavelength 250 to 450 nm) up to 250 mJ/cm² through the step tablet using a direct-write exposure machine “DilMPACTMms60” manufactured by Oak Corporation. This test piece was developed in a manner similar to the development performed in the test piece manufacturing step. The largest step number where 100% of a sensitivity step number after the development remains was evaluated as a sensitivity. Larger step number shows that the exposure property (sensitivity) is better.

(3) Resolution

For a test piece having a cured coating designed to have a line width of 30 μm to 120 μm which was manufactured in conformity with the test piece manufacture step except that the thickness of the cured coating was 40 μm, the cured coating having a thinnest line width remaining on the wiring board was observed by visual inspection and evaluated as a resolution. Note that, the line was formed using methods of exposure and development which are the same as those in the aforementioned test piece manufacture step.

(4) Cross-Sectional Shape

The wiring board having the cured coating of a width of 100 μm formed thereon which was manufactured in conformity with the aforementioned test piece manufacturing step was cut, and a cut surface was sealed with a sealing resin (epoxy resin). Next, the sealed cross section is polished, and thereafter, measurement was performed for the cross section of the cured coating using a metallograph or a scanning electron microscope, and a width (x) of a front face-side end portion and a width (y) of a bottom-side (deeper-side) end portion were measured. A cross-sectional shape in which y is narrower than x by 15 μm on each side was classified as “ ∞, a cross-sectional shape in which y is narrower than x by greater than or equal to ◯ 15 μm and less than 20 μm on each side was classified as “ ”, and a cross-sectional shape in which y is narrower than x by greater than or equal to 20 μm on Δ each side was classified as “ ”.

A result of evaluation is × shown in Table 2 below.

TABLE 2

| | EXAM- | EXAM- | EXAM- | EXAM- | EXAM- | EXAM- | EXAM- | EXAM- | EXAM- | EXAM- |
|---|---|---|---|---|---|---|---|---|---|---|
| | PLE 1 | PLE 2 | PLE 3 | PLE 4 | PLE 5 | PLE 6 | PLE 7 | PLE 8 | PLE 9 | PLE 10 |
| TRANSMITTANCE | ∘ | ∘ | ∘ | ∘ | ∘ | ∘ | ∘ | ∘ | ∘ | ∘ |
| SENSITIVITY | 8 | 7 | 9 | 7 | 9 | 7 | 7 | 8 | 6 | 9 |
| RESOLUTION | 70 μm | 80 μm | 70 μm | 80 μm | 70 μm | 90 μm | 70 μm | 70 μm | 120 μm | 70 μm |
| CROSS SECTIONAL | ∘ | ∘ | ∘ | ∘ | ∘ | ∘ | ∘ | ∘ | ∘ | Δ |
| SHAPE | | | | | | | | | | |

| | COMPARATIVE | COMPARATIVE | COMPARATIVE | COMPARATIVE | COMPARATIVE |
|---|---|---|---|---|---|
| | EXAMPLE 1 | EXAMPLE 2 | EXAMPLE 3 | EXAMPLE 4 | EXAMPLE 5 |
| TRANSMITTANCE | ∘ | ∘ | ∘ | ∘ | x |
| SENSITIVITY | 4 | 8 | 5 | 8 | 8 |
| RESOLUTION | * | 70 μm | 120 μm | 90 μm | 100 μm |
| CROSS SECTIONAL | — | x | x | x | x |
| SHAPE | | | | | |

“*” INDICATES THAT LINE OF CURED COATING IS NOT YET FORMED

From Examples in Table 2, it can be seen that with a photosensitive resin composition containing a photopolymerization initiator that is an oxime ester compound and a photopolymerization initiator that is an aminocarbonyl compound having a tertiary amino group, even in a case of exposure by direct-writing, undercutting of the curable coating layer can be suppressed without degrading transmittance, sensitivity and resolution, and a cured coating having an improved cross-sectional shape was obtained. From Examples 1 to 9 and Example 10, it can be seen that when 6 to 12 parts by mass of an aminocarbonyl compound having a tertiary amino group is contained with respect to 100 parts by mass of the carboxyl group-containing photosensitive resin, undercutting of the cured coating was positively inhibited, and the cured coating having an improved cross-sectional shape was obtained. Also, from Examples 1 to 9, it can be seen that the improved cross-sectional shape of the cured coating was obtained for any of 0.2 to 0.4 parts by mass of the content of the oxime ester compound with respect to 100 parts by mass of the carboxyl group-containing photosensitive resin.

From Examples 1 to 9, it can be seen that the improved cross-sectional shape of the cured coating was obtained for any of 22.5 to 60 parts by mass of the aminocarbonyl compound having a tertiary amino group with respect to 1.0 parts by mass of the oxime ester compound. Also, from Examples 1 to 9, it can be seen that the improved cross-sectional shape of the cured coating was obtained when an α-aminoalkyl phenone photopolymerization initiator, an acyl phosphine oxide photopolymerization initiator, and a thioxanthone photopolymerization initiator were further combined in addition to the oxime ester compound and the aminocarbonyl compound having a tertiary amino group. Also, from Examples 3, 5 and 10, it can be seen that an improved sensitivity was obtained when the content of the oxime ester compound was 0.4 parts by mass with respect to 100 parts by mass of the carboxyl group-containing photosensitive resin.

On the other hand, from Comparative Examples 1 to 5, it can be seen that with the photosensitive resin composition that contains none or one of the oxime ester compound and the aminocarbonyl compound having a tertiary amino group, a significant undercut occurred in the cross-sectional shape of the cured coating and photo-curing reaction did not advance to a deeper part of the coating.

### INDUSTRIAL APPLICABILITY

The photosensitive resin composition of the present disclosure is useful in the field of, for example, photo-curing a coating with a direct-write exposure, since, during the exposure, photopolymerization reaction of the coating is promoted as compared to the related art, and a sufficient photo-curing can be obtained up to a deeper part of the coating.

What is claimed is:

1. A photosensitive resin composition comprising:
a carboxyl group-containing photosensitive resin;
a photopolymerization initiator, wherein the photopolymerization initiator comprises an oxime ester compound and an aminocarbonyl compound having a tertiary amino group;
a compound having an ethylenic unsaturated group;
a non-reactive diluent; and
an epoxy compound.

2. The photosensitive resin composition according to claim 1, wherein 6.0 parts by mass to 12.0 parts by mass of the aminocarbonyl compound having a tertiary amino group is contained with respect to 100 parts by mass of the carboxyl group-containing photosensitive resin.

3. The photosensitive resin composition according to claim 1, wherein 0.2 parts by mass to 0.4 parts by mass of the oxime ester compound is contained with respect to 100 parts by mass of the carboxyl group-containing photosensitive resin.

4. The photosensitive resin composition according to claim 1, further comprising a coloring agent.

5. A printed circuit board having a cured film obtained by photo-curing the photosensitive resin composition according to claim 1.
